(19) United States
(12) Patent Application Publication
(10) Pub. No.: US 2026/0342353 A1
(43) Pub. Date: Oct. 29, 2026

(54) DIGITAL-TO-ANALOG CONVERTER WITH BOOST AND CAPACITIVE DIGITAL-TO-ANALOG CONVERTER

(71) Applicant: TEXAS INSTRUMENTS INCORPORATED, Dallas, TX (US)

(72) Inventors: Abhishek Ghosh, Bangalore (IN); Rajavelu Thinakaran, Bangalore (IN); Rahul Kumar, Bangalore (IN); Rahul Shaw, Bangalore (IN)

(21) Appl. No.: 19/399,963

(22) Filed: Nov. 25, 2025

(30) Foreign Application Priority Data
Apr. 25, 2025 (IN) 202541039842
Apr. 25, 2025 (IN) 202541039896

(51) Int. Cl. H03M 1/66

(52) U.S. Cl. CPC H03M 1/662

(57) ABSTRACT

An apparatus includes a first digital-to-analog converter (DAC) having an input configurable to receive a digital code and having an output. An amplifier has an input coupled to the output of the first DAC. A second DAC has an input and an output. The input of the second DAC is configurable to receive a difference between a first digital code and a second digital code. The output of the second DAC is coupled to the input of the amplifier. The second DAC is configurable to provide into the input of the amplifier a current having a magnitude based on the difference between the first and second digital codes.

### CROSS-REFERENCE TO RELATED APPLICATIONS

This application claims priority to India Provisional Appl. No. 202541039896 filed Apr. 25, 2025 and titled “Precision Multiplying DACs With Improved Settling Time”, and India Provisional Appl. No. 202541039842 filed April 25 and titled “Precision Multiplying DACs With Improved Settling Time,” 2025, both of which are hereby incorporated by reference.

### BACKGROUND

The present disclosure relates generally to electronic systems and methods, and, in particular embodiments, to a digital-to-analog converter (DAC) with boost and capacitive DAC.

### BACKGROUND

A digital-to-analog converter (DAC) converts a digital input value to an analog output signal. One type of DAC is a multiplying DAC (MDAC). Most, if not all, DACs receive a reference voltage which is used in the conversion process. An MDAC may be capable of two modes of operation. In the first mode, the reference voltage is fixed and the digital codes are time-varying. In the second mode, the digital code is fixed and the reference voltage is time-varying.

### SUMMARY

In one embodiment, an apparatus includes a first digital-to-analog converter (DAC) having an input configurable to receive a digital code and having an output. An amplifier has an input coupled to the output of the first DAC. A second DAC has an input and an output. The input of the second DAC is configurable to receive a difference between a first digital code and a second digital code. The output of the second DAC is coupled to the input of the amplifier. The second DAC is configurable to provide into the input of the amplifier a current having a magnitude based on the difference between the first and second digital codes.

In another embodiment, an apparatus includes a first resistive DAC network having an input and terminals and a first switch having control inputs, terminals, and an output. The terminals of the first switch are coupled to respective terminals of the first resistive DAC network. A second resistive DAC network has an input and terminals. A second switch has control inputs, terminals, and an output. The terminals of the second switch are coupled to respective terminals of the second resistive DAC network, and the output of the second switch is coupled to the output of the first switch. A logic circuit has an input and outputs. The input is configurable to receive a difference between a first digital code and a second digital code. The outputs of the logic circuit are coupled to respective control inputs of the first and second switches. The logic circuit includes a pulse generator configured to generate a pulse to cause at least one of the first or second resistive DAC networks to generate a current for a time duration based on a width of the pulse. The current has an amplitude based on the difference between the first and second digital codes.

In yet another embodiment, an apparatus includes a first DAC having an input configurable to receive a reference voltage having a first polarity and having an output. An amplifier has an input coupled to the output of the first DAC. A second DAC has an input and an output. The input is configurable to receive the reference voltage having a second polarity different than the first polarity. The output of the second DAC is coupled to the input of the amplifier.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1A is a circuit schematic of an MDAC, in accordance with an embodiment of the present disclosure;

FIG. 1B are waveforms illustrating a settling time problem associated with the MDAC of FIG. 1 when the MDAC operates in a mode in which the reference voltage is fixed and the digital codes are time-varying;

FIG. 1C are waveforms illustrating reduced performance of the MDAC of FIG. 1 in a frequency range in a mode in which the digital code is fixed and the reference voltage is time-varying;

FIG. 2 is a circuit schematic of an MDAC including a boost DAC and a multiplying capacitive DAC (MCDAC), in accordance with an embodiment of the present disclosure;

FIGS. 3A and 3B are waveforms illustrating the operation of the boost DAC, in accordance with an embodiment of the present disclosure;

FIG. 4A is a circuit schematic of the resistive networks within the boost DAC, in accordance with an embodiment of the present disclosure;

FIG. 4B is a circuit schematic of a logic circuit to control switches within the resistive networks of the boost DAC, in accordance with an embodiment of the present disclosure;

FIG. 5 includes waveforms illustrating the operation of a pulse generator within the logic circuit of FIG. 4B;

FIG. 6 is a schematic diagram including a multiplexer and a multiplier for scaling the digital code difference for use in the boost DAC, in accordance with an embodiment of the present disclosure;

FIG. 7 is a schematic diagram of the MCDAC of FIG. 2, in accordance with an embodiment of the present disclosure; and

FIG. 8 includes graphs illustrating the frequency performance of the MCDAC of FIG. 7, in accordance with an embodiment of the present disclosure.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be obtained without one or more of the specific details, or with other methods, components, materials and the like. In some cases, known structures, materials or operations are not shown or described in detail so as not to obscure the different aspects of the embodiments. References to “an embodiment” or “an example” in this description indicate that a particular configuration, structure or feature described in relation to the embodiment is included in at least one embodiment. Consequently, phrases such as “in one embodiment” or “in one example” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

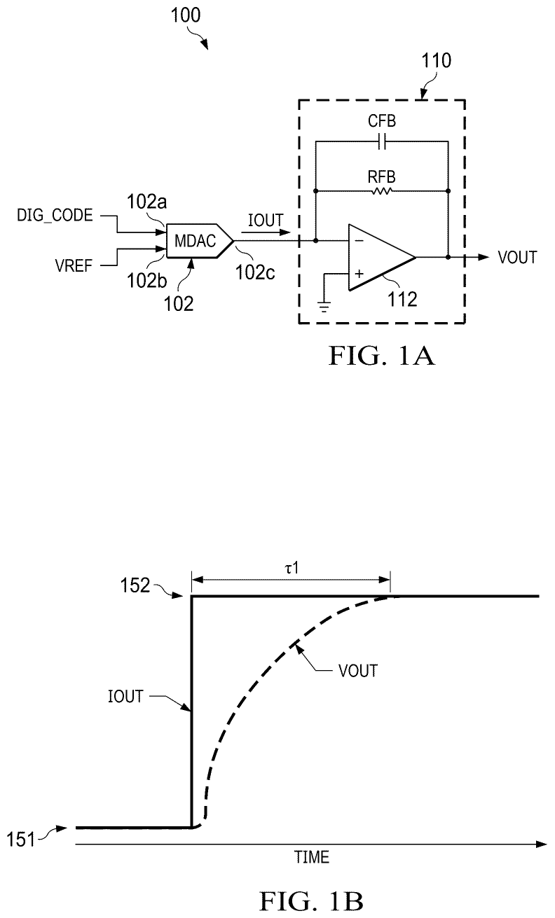

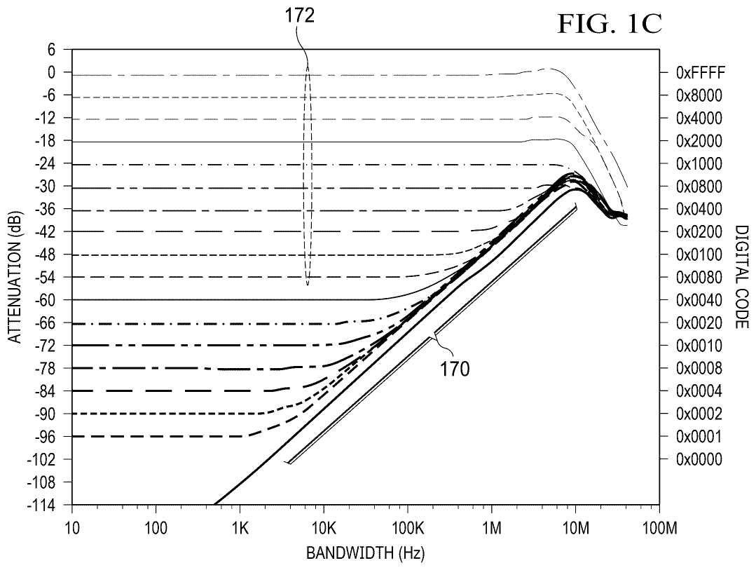

FIG. 1 is a circuit schematic of a conversion device 100, in accordance with an embodiment of the present disclosure. In the embodiment of FIG. 1, conversion device 100 includes an MDAC 102 coupled to an amplifier 110. MDAC 102 has input terminals 102a and 102b which receive a digital code (DIG_CODE) and a reference voltage VREF, respectively. In one embodiment, DIG_CODE is a 16-bit value but can be other than 16-bits in other embodiments. MDAC 102 also has an output 102c. Amplifier 110 includes an operational-amplifier 112, a resistor RFB, and a capacitor CFB. Resistor RFB and capacitor CFB are coupled in parallel between the output of operational-amplifier 110 and the negative input of the operational-amplifier. The positive input of the operational-amplifier is coupled to ground in this example. The output 102c of MDAC 102 is coupled to the negative input of operational-amplifier 112.

MDAC 102 generates an output analog current IOUT based on a product of DIG_CODE and VREF. Amplifier 110 is a current-to-voltage (I2V) converter which converts IOUT to an output voltage VOUT. The relationship between VOUT, DIG_CODE, and VREF may be given by:

$$VOUT = \frac{DIG\_CODE}{{2}^{n}} * V R E F \qquad ( Eq . 1 )$$

where n is the resolution of the converter (e.g., n is 16 for a 16-bit converter).

In the mode in which VREF is constant and DIG_CODE is time-varying, amplifier 110 may have a settling time problem. The settling time of conversion device 100 is based, at least in part, on the values of resistor RFB and capacitor CFB. For example, the settling time, τ1, is given by:

$$τ 1 = ( RFB ⋆ CFB ) + \frac{1}{β {ω}_{UGB}} \qquad ( Eq . 2 )$$

where β is the feedback factor of amplifier 110 and ω_{UGB} is the unity-gain frequency of amplifier 110. In an example,

$$β = \frac{R D A C}{R D A C + R F B} ,$$

where RDAC is the resistance of the resistive network within MDAC 102, discussed below, for a given DIG_CODE value. Eq. 2 illustrates that the settling time of the conversion device 100 is largely a function of the product of RFB and CFB.

In some embodiments, conversion device 100 may be integrated into an integrated circuit (IC). A discrete implementation may also be possible.

FIG. 1B includes example graphs of IOUT from MDAC 102 for a change in digital code from a first digital code to a second digital code. The second digital code may be larger than the first digital code. In response to an increase in digital code, IOUT increases rapidly from a first current level 151 to a second current level 152. In response to an increase in IOUT, amplifier 110 causes VOUT to increase as well. However, the settling time of amplifier 110 is such that VOUT may take a relatively long time to settle at the new/higher value. For some applications (e.g., fast precision DACs), the settling time of conversion device 100 may be problematic.

In the mode in which DIG_CODE is fixed and VREF is time-varying, the frequency response of conversion device 100 may be problematic. FIG. 1C includes graphs of the frequency response of conversion device 100 for various digital codes listed on the right-hand Y-axis of the graph. For example, for a digital code 0x0001 and at a VREF of 10 Hz, the attenuation of VREF is −96 dB. Similarly, at 10 Hz, the attenuation values for digital codes 0x0002 and 0x0004 are −90 dB and −84 dB, respectively. However, at frequencies greater than about 2 KHz, the attenuation values change (e.g., decrease for digital codes between, for example, 0x0001 and 0x1000, as illustrated at 170. As shown in the example of FIG. 1C, the attenuation values for at least some of the codes between 0x0001 and 0x1000 are approximately the same for any given frequency. For example, at a frequency of 100 KHz, the attenuation values for digital codes 0x0001 to 0x0040 are all between approximately −60 dB and −66 dB. Accordingly, the conversion device 100 may be limited to VREF frequencies below approximately 2 KHz if the target resolution is to be maintained. If the conversion device is intended to operate with VREF frequencies as high as, e.g., 100 KHz, digital codes equal to and larger than 0x0080 maintain their attenuation values. Accordingly, for any given frequency above, e.g., 2 KHz, the attenuation values for a lower range of digital codes may be distorted but the attenuation values at a higher range of digital codes may not be distorted. The embodiments described herein provide solutions to the above-described settling time and frequency problems.

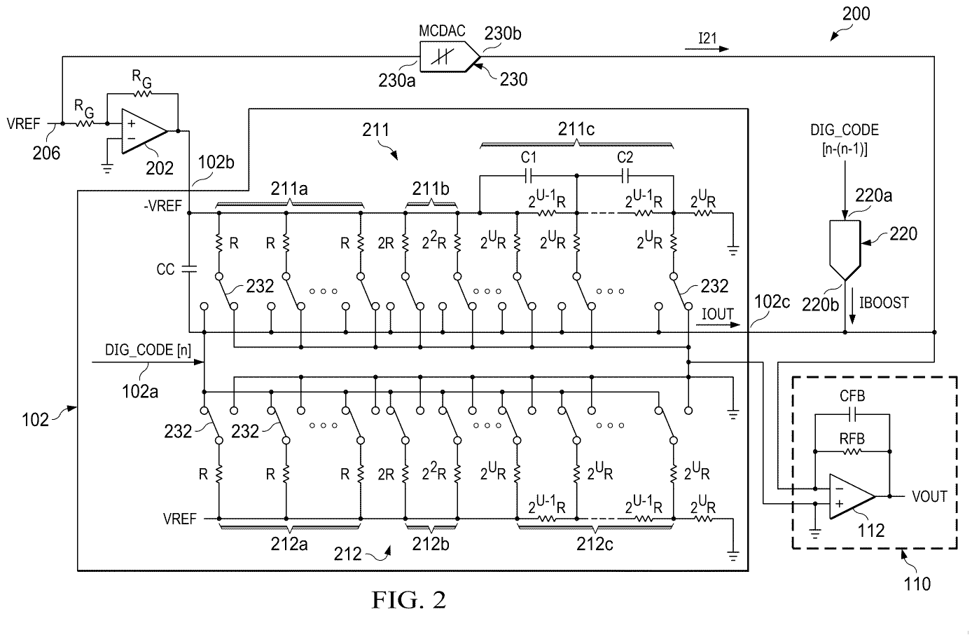

FIG. 2 is a schematic diagram of a conversion device 200 which includes MDAC 102, amplifier 110, a boost DAC 220, and a multiplying capacitive DAC (MCDAC) 230 in accordance with an embodiment of the present disclosure. As described herein, boost DAC 220 may help to address the settling time problem, and MCDAC 230 may help to increase the frequency range of the conversion device. Boost DAC 220 may be operative when MDAC 102 operates in the mode in which the digital code is time-varying and VREF is fixed. In such a mode, MCDAC 230 may be disabled. MCDAC 230 is operative when MDAC 102 operates in the mode in which VREF is time-varying and the digital code is fixed. In such a mode, boost DAC 220 may be enabled or disabled.

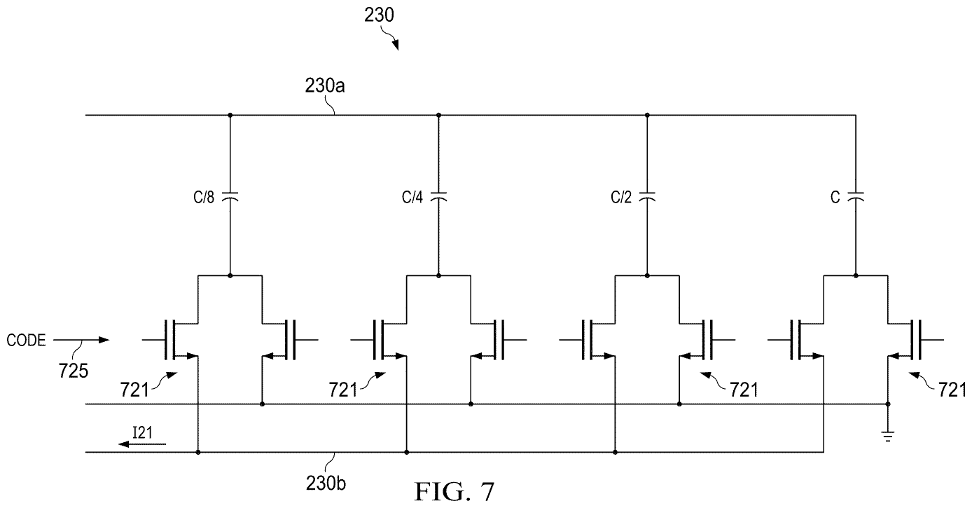

In the embodiment of FIG. 2, MDAC 102 is a resistive DAC including a first resistor network 211 and a second resistor network 212. In other embodiments, MDAC 102 may have first resistor network 211 but not second resistor network 212. Each resistor network 211 and 212 may have one or more thermometric segments, one or more binary-weighted segments, and one or more R2R segments. For example, first resistor network 211 has thermometric segments 211a, binary-weighted segments 211b, and R2R segments 211c. Similarly, second resistor network 212 has thermometric segments 212a, binary-weighted segments 212b, and R2R segments 212c. Each segment (e.g., thermometric binary-weighted, or R2R segments has a switch 232 configurable to electrically couple the resistor(s) of that segment to the output 102c or to a reference terminal (e.g., ground). A bit from the digital code DIG_CODE is provided to a control input of each switch. In one example, one or more most significant bits (MSBs) control the switches 232 of the thermometric segments, and bits of the least significant bits control the switches of the binary-weighted and R2R segments. The segmentation of the resistor network (e.g., the number of thermometric, binary-weighted, and R2R segments) may be application-specific. Based on the digital code which controls the states of the switches 232, current from input 102b either flows through a given segment to the output 102c or to ground. Current IOUT is the sum of the currents through the segments that flow through to output 102c. A positive digital code activates the switches of the first resistive network 211, and a negative digital code activates the switches 232 of the second resistive network 212. Current IOUT is positive (relative the direction of the arrow for IOUT in FIG. 2) when the digital code is, for example, greater than a mid-range value for the digital code, and current IOUT is negative when the digital code is less than the mid-range value for the digital code. FIG. 2 also illustrates parasitic capacitances CC, C1, and C2. For the application in which VREF is time-based, such parasitic capacitances at least in part cause the frequency performance problem at higher frequencies of VREF and are discussed below with respect to FIG. 7.

In some embodiments, amplifier 110 may be an inverting amplifier. Accordingly, in the embodiment of FIG. 2, conversion device 200 may include an inverting buffer 202 coupled between input terminal 102b of MDAC 102 and a terminal 206 which has VREF. Inverting buffer 202 inverts the polarity of VREF at the input terminal 102b of MDAC. MCDAC 230, described below, has an input 230a and an output 230b. Input 230a is coupled to terminal 206 and receives VREF. Output 230b of MCDAC 230 is coupled to output 102c of MDAC 102.

Boost DAC 220 has an input 220a and an output 220b. The input 220a of boost DAC 220 receives a digital code difference. In one example, the digital code difference is the difference between a current digital code and a previous digital code, e.g., DIG_CODE[n]-DIG_CODE[n−1], where DIG_CODE(n) is the current digital code and DIG_CODE(n−1) is the preceding digital code. Output 220b is coupled to output 102c of MDAC 102. Boost DAC 220 generates a current pulse IBOOST at output 220b. Current pulse IBOOST is added to output current IOUT from MDAC 102 and the sum of IBOOST and IOUT is converted to output voltage VOUT by amplifier 110. The magnitude of IBOOST is based on the digital code difference, e.g., a larger digital code difference results in a larger magnitude of IBOOST and a smaller digital code difference results in a smaller magnitude of IBOOST. The width of the current pulse IBOOST is based on the bandwidth of amplifier 110. The bandwidth of amplifier 110 is based, at least in part, on the values of resistor RFB and capacitor CFB in the feedback path of amplifier 110. The boost DAC provides the current pulse IBOOST into the input of the amplifier for a fixed duration of time irrespective of the digital code difference.

In some embodiments, conversion device 200 may be integrated into an integrated circuit (IC). A discrete implementation may also be possible.

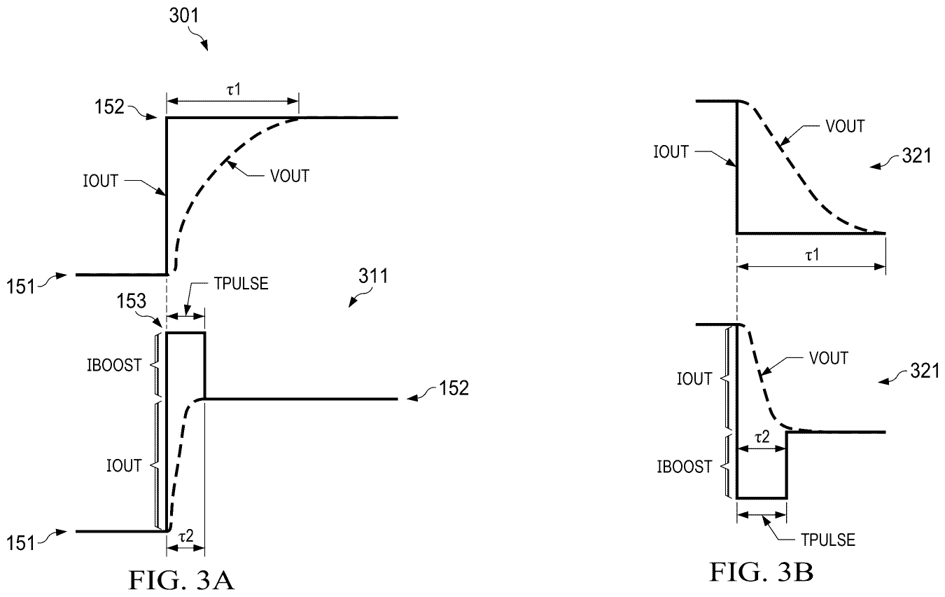

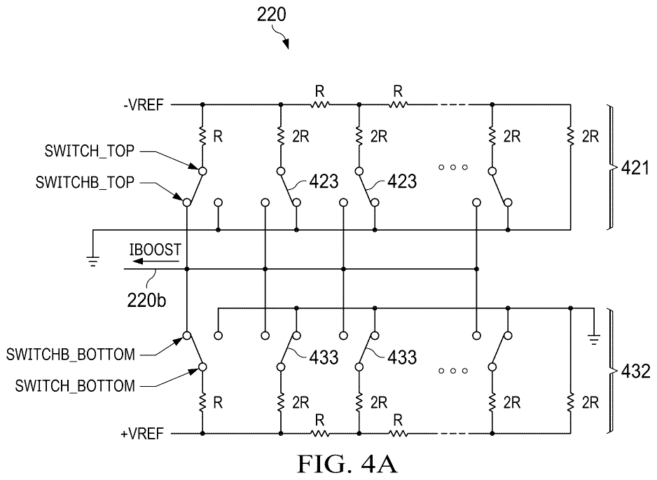

FIGS. 3A and 3B include waveforms illustrating the operation of boost DAC 220. FIG. 3A has example waveforms at 301 for IOUT and VOUT for conversion device 100 without a boost DAC and waveforms at 311 for IOUT, IBOOST, and VOUT for conversion device 200 with boost DAC. For FIG. 3A (repeated from FIG. 1B for convenience), the previous digital code, DIG_CODE(n−1), is a positive value resulting in IOUT at current level 151. The current digital code, DIG_CODE(n), also is a positive value but larger than the previous digital code thereby resulting in a larger current level 152 for IOUT. The difference between the current digital code and the previous digital code, DIG_CODE[n]-DIG_CODE[n−1] also is a positive value. At 311, the IBOOST current pulse adds to IOUT from MDAC 102 producing a IOUT at current level 153 during the pulse time period TPULSE that is larger than current levels 151 or 152. IOUT being larger at current level 153 causes VOUT to rise more quickly than at 301 (which lacks the boost DAC). As a result of the current pulse IBOOST, the settling time τ2 of the conversion device 200 with boost DAC 220 is smaller than the settling time τ1 of conversion device 100 without boost DAC 220. FIG. 3B is a similar example to the example of FIG. 3A but for a negative current IOUT and for a negative difference between DIG_CODE(n) and DIG_CODE(n−1).

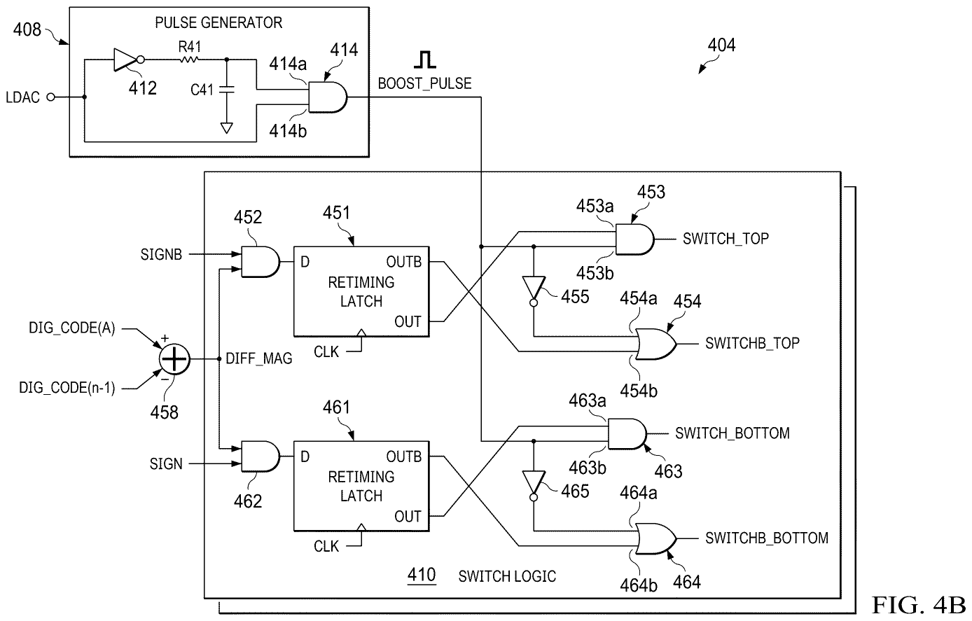

FIGS. 4A and 4B include circuit schematics of boost DAC 220 in accordance with an embodiment of the present disclosure. Boost DAC 220 may include resistive networks as was the case for MDAC 102. FIG. 4A is a circuit schematic of the resistive networks 421 and 432 of boost DAC 120. Each of resistive networks 421 and 432 may include one or more thermometric segments, one or more binary-weighted segments, and one or more R2R segments. Boost DAC 220 may be a lower resolution DAC than MDAC 102 and accordingly, the number of segments of boost DAC 220 may be fewer than the number of segments of MDAC 102. Resistive network 421 may receive the reference voltage from the output of buffer 202 (e.g., −VREF), and resistive network 432 may receive the reference voltage from the input of buffer 202 (e.g., +VREF). The outputs of resistive networks 421 and 432 are coupled together at output 220b of boost DAC 220.

The segments of resistive networks 421 and 432 include switches 423 and 433, respectively, to couple each segment of the resistive networks 421 and 432 to the output 220b or to ground based on a bit of the digital code difference. The digital code difference, DIG_CODE[n]-DIG_CODE[n−1], includes multiple bits. Each bit controls a corresponding switch 423 or 433 based on whether the digital code difference is a positive value or a negative value. For a positive digital code difference, the bits control the switches 423 of resistive network 421. For a negative digital code difference, the bits control the switches 433 of resistive network 432.

The control signals to each switch 423 of resistive network 421 include SWITCH_TOP and SWITCHB_TOP for a corresponding bit of the digital code difference. The control signals to each switch 433 of resistive network 432 include SWITCH_BOTTOM and SWITCHB_BOTTOM for a corresponding bit of the digital code difference. SWITCHB_TOP is the logical inverse of SWITCH_TOP and SWITCHB_BOTTOM is the logical inverse of SWITCH_BOTTOM. In one example, responsive to SWITCH_TOP and SWITCHB_TOP being logic “1” and “0,” respectively, the corresponding switch 423/433 may be coupled to output 220b, and responsive to SWITCH_TOP and SWITCHB_TOP being logic “0” and “1,” the corresponding switch 423/433 may be coupled to ground. Similarly, SWITCH_BOTTOM being logic 1 (SWITCHB_BOTTOM=0) connects the corresponding switch 433 to output 220b, and SWITCH_BOTTOM being logic 0 (SWITCHB_BOTTOM=1) connects the corresponding switch 433 to ground.

For a positive digital code difference, a bit within the code difference that is a “1” electrically couples the corresponding resistive segment within resistive network 421 to the output 220b, and a bit that is a “0” electrically couples the corresponding resistive segment within resistive network 421 to ground. For a positive digital code difference, switches 433 are controlled to electrically couple the segments of the second resistive network 432 to ground. For a negative digital code difference, a bit within the code difference that is a “1” electrically couples the corresponding resistive segment to the output 220b, and a bit that is a “0” electrically couples the corresponding resistive segment to ground. For a negative digital code difference, switches 423 are controlled to electrically couple the segments of the first resistive network 421 to ground.

FIG. 4B is a circuit schematic of a logic circuit 404 to generate the switch control signals SWITCH_TOP/SWITCHB_TOP and SWITCH_BOTTOM/SWITCHB_BOTTOM, in accordance with an embodiment of the present disclosure. Logic circuit 404 includes a pulse generator 408, switch logic 410, and a subtractor 458. Pulse generator 408 receives a signal LDAC. LDAC may be generated by MDAC 102 when a new digital code is present at the input terminal 102a of MDAC 102. Pulse generator 408 generates a pulse signal BOOST_PULSE. As described below, the width of BOST_PULSE is based on the bandwidth of amplifier 110. Subtractor 458 subtracts the previous digital code DIG_CODE(n−1) from the current digital code DIG_CODE(n) to produce a multi-bit digital code difference. Logic circuit 404 includes a separate switch logic 410 for each bit of the digital code difference. Each switch logic 410 controls the switches of the corresponding segment of the resistive networks 421 and 432. The digital code difference includes a magnitude value, DIFF_MAG, and a sign bit SIGN. SIGN indicates whether the difference is positive (SIGN=0) or negative (SIGN=1). SIGNB is the logical inverse of SIGN. Each bit of DIFF_MAG is provided to a corresponding switch logic 410. Based on BOOST_PULSE, SIGN, and DIFF_MAG, each switch logic 410 generates switch control signals SWITCH_TOP, SWITCHB_TOP, SWITCH_BOTTOM, and SWITCHB_BOTTOM to control the corresponding switches of resistive networks 421 and 432.

Pulse generator 408 may include an inverter 412, a resistor R41, and a capacitor C41, and an AND gate 414. LDAC signal may transition from logic low to logic high when a new digital code is present at input terminal 102a. LDAC is inverted by inverter 412. The output of inverter 412 transitions from logic high to low when a new digital code is present. Resistor R41 and capacitor C41 form a filter, e.g., a low-pass filter that delays the transition of the falling edge at the output of inverter 412 into the input 414a of AND gate 414. Input 414a of AND gate receives LDAC. The input 414b transitions to a logic high in response to a rising edge of LDAC, but a delay is present for input 414a to transition from logic high to low. The period of time that the input 414a of AND gate 414 remains high is based on the time constant of the low-pass filter formed by the resistor R41 and capacitor C41. AND gate 414 produces a signal pulse BOOST_PULSE at its output which is logic high in response to LDAC becoming logic high. The pulse width of BOOST_PULSE is based on the time constant of the low-pass filter formed by the resistor R41 and capacitor C41.

The resistance of resistor R41 is approximately equal to the resistance of resistor RFB in amplifier 110. The capacitance of capacitor C41 is approximately equal to the capacitance of capacitor CFB in amplifier 110. Accordingly, the pulse width of BOOST_PULSE is based on the bandwidth of amplifier 110. For example, a lower bandwidth of amplifier 110 also means that the pulse width of BOOST_PULSE is longer, and a higher amplifier bandwidth means that the pulse width of BOOST_PULSE is shorter.

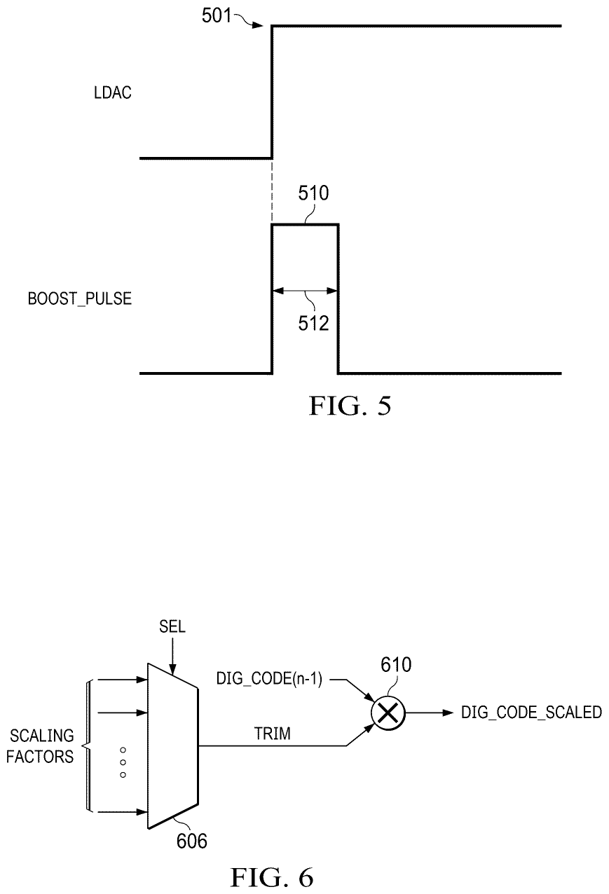

FIG. 5 is a timing diagram illustrating LDAC and BOOST_PULSE, according to an embodiment of the present disclosure. Upon the occurrence of a rising edge 501 of LDAC (signifying the presence of a new digital code), pulse generator 408 generates a pulse for BOOST_PULSE. The pulse width 512 of BOOST_PULSE is based on the resistance and capacitance values for resistor R41 and capacitor C41, as described above. BOOST_PULSE is provided to switch logic 410 to generate control signals for the switches of the resistive network 421 or 432 to generate the IBOOST current for a length of time corresponding to pulse width 512.

Referring again to FIG. 4B, each switch logic 410 may include retiming latches 451 and 461, AD gates 452, 453, 462, and 463, OR gates 454 and 464, and inverters 455 and 465. One input of AND gates 452 and 462 may receive the corresponding bit of DIFF_MAG. The other inputs of AND gates 452 and 462 may receive SIGN and SIGNB, respectively. For a positive digital code difference, the sign bit SIGN is a ‘0’ and SIGNB is a ‘1’. With SIGNB equal to logic 1, the output from AND gate 452 will be equal to the corresponding bit of DIFF_MAG. The output of AND gate 452 is coupled to the data (D) input of the retiming latch 451. The output of AND gate 462 is coupled to the D input of the retiming latch 461. The outputs OUT of retiming latches 451 and 461 are coupled to inputs 453a and 463a of AND gates 453 and 463, respectively. The inverse outputs OUTB of retiming latches 451 and 461 are coupled to inputs 454b and 464b of OR gates 454 and 464, respectively. The output of AND gate 414 is coupled to the inputs 453b and 463b of AND gate 453 and OR gate 463, respectively. Accordingly, inputs 453b and 463b of AND gate 453 and OR gate 463 receive BOOST_PULSE. The output of AND gate 414 is coupled through inverters 455 and 465 to the inputs 454a and 464a of OR gates 454 and 464, respectively. Accordingly, inputs 454a and 464a of OR gates 454 and 464 receive the logical inverse of BOOST_PULSE.

A clock signal (CLK) clocks the retiming latches 451 and 461. Retiming latches 451 and 461 help to control the timing of boost DAC 220 such that the boost DAC's transitions occur at approximately the same time. When SIGNB is logic 1 (e.g., positive digital code difference), the output “OUT’ from the retiming latch 451 is equal to the corresponding bit of DIFF_MAG, and the inverse output ‘OUTB’ from retiming latch 451 is the logical inverse of the corresponding bit of DIFF_MAG. When BOOST_PULSE occurs and is logic high, the output signal SWITCH_TOP from AND gate 453 is equal to the corresponding bit of DIFF_MAG. The output signal SWITCHB_TOP from OR gate 454 is logical inverse of the corresponding bit of DIFF_MAG.

When SIGN is logic 0 (e.g., positive digital code difference), the outputs of AND gates 462 of all switch logic 410 for the bits of the resistive networks 421 and 432 is a logic 0. As a result, OUT of retiming latch 461 is a logic 0, and SWITCH_BOTTOM is logic 0 and SWITCHB_BOTTOM is logic 1. With SWITCH_BOTTOM and SWITCHB_BOTTOM at logic levels 0 and 1, respectively, all of the switches 433 of resistive network 432 in boost DAC 220 electrically couple the corresponding resistive segments to ground instead of output 220b.

The operation of switch logic 410 is similar when the digital code difference is negative. In that case, SIGN and SIGNB are logic 1 and 0, respectively. With SIGN at logic 1, the bits of DIFF_MAG are clocked through the corresponding retiming latches 461 and, when BOOST_PULSE is logic high, through AND gate 463 as signal SWITCH_BOTTOM. Signal SWITCHB_BOTTOM from OR gate 464 is the logical inverse of SWITCH_BOTTOM for bit of the DIFF_MAG. With SIGNB at logic 0, signals SWITCH_TOP and SWITCHB_TOP from AND gate 453 and OR gate 454, respectively, are logic 0 and 1, respectively.

In some embodiments of the present disclosure, boost DAC 220 introduces the additional boost current IBOOST upon a change in digital codes if the digital code difference is less than a threshold. In one embodiment, the threshold may be 0x8000. For digital code differences greater than the threshold (e.g., greater than 0x8000), the change in output current IOUT from MDAC 102 may be large enough that the settling time is short enough that boost DAC 220 may not provide much of a benefit. Subtractor 458 in FIG. 4B may include logic, e.g., a comparator, to compare the absolute value of digital code difference to a threshold (e.g., 0x8000). If the absolute value of the digital code difference is less than the threshold, subtractor 458 outputs the signed digital code difference as described above. If the absolute value of the digital code difference is greater than the threshold, subtractor 458 outputs a DIFF_MAG bit equal to logic 0 to each switch logic 410 thereby causing SWITCH_TOP and SWITCHB_TOP to be logic 0 and 1, respectively, and SWITCH_BOTTOM and SWITCHB_BOTTOM to be logic 0 and 1, respectively. With the switch signals at such states, all of the switches of the resistive networks 421 and 432 are coupled to ground.

FIG. 6 is a circuit schematic for scaling the digital code difference, in accordance with an embodiment of the present disclosure. In this embodiment, a digital multiplier 610 multiplies DIG_CODE[n]-DIG_CODE[n−1] by a trim value TRIM to thereby scale the digital code difference. The trim value may be based on component mismatches, process variations, voltage differences, parasitic inductance of traces, etc. The value of TRIM may be determined during a trim process. A multiplexer 606 receives one or more scaling factors. During the trim process, the appropriate scaling factor is determined, and a selection value SEL is thereby determined to select the trimmed scaling factor as TRIM to the multiplier 610.

As described above, in a mode of operation of MDAC 102, the digital code may be fixed and the reference voltage may be time-varying. In such a mode, the parasitic capacitances CC, C1, and C2 noted above may contribute to the frequency performance problem described above with respect to FIG. 1C. Parasitic capacitance C1 is a coupling capacitance that may couple VREF to the output 102c. The coupling of VREF into the output 102c is greater at higher frequencies of VREF. The R2R segments of MDAC 102 also have parasitic capacitances C1 and C2. For example, each R2R segment may have a parasitic capacitance across it. The R2R segments correspond to the lower order bits of MDAC 102.

In the absence of the MCDAC 230, at relatively high frequencies, the output voltage VOUT can be written as:

$$VOUT ( k ) = \frac{C C}{C F B} V R E F + \frac{C [ k ]}{C F B} VREF \qquad ( Eq . 3 )$$

where CFB is the feedback capacitance in amplifier 110 and C[k] is the parasitic capacitance within the R2R segments corresponding to code k (e.g., C1, C2, etc.). Per Eq. (3), Per Eq. (3), VOUT may be influenced by the parasitic capacitances C1 and C[k], particularly at higher frequencies (e.g., greater than 2 KHz).

Referring again to FIG. 2, MCDAC 230 receives the reference voltage at an opposite polarity as MDAC 102. The output current from MCDAC 230 is I21 and is a positive current in the direction of the arrow. Because MCDAC 230 operates with a reference voltage having an opposite polarity as MDAC 102, I21 from MCDAC 230 has an opposite polarity as IOUT from MDAC 102. For example, if VREF is a positive voltage, then the reference voltage to MCDAC 230 is positive and the reference voltage to MDAC 102 is negative. Accordingly, I21 is a positive current and IOUT is a negative current relative to the direction of the corresponding arrows. Similarly, if VREF is a negative voltage, then the reference voltage to MCDAC 230 is negative and the reference voltage to MDAC 102 is positive, and I21 and IOUT are negative and positive currents, respectively. As further described below, MCDAC 230 provides a correction current to output 102c.

FIG. 7 is a circuit schematic of MCDAC 230, in accordance with an embodiment of the present disclosure. In this embodiment, MCDAC 230 is a binary-weighted, switched capacitive DAC. In FIG. 7, MCDAC 230 includes binary-weighted capacitors C, C/2, C/4, and C/8, although the number of segments may be application-specific. Each binary-weighted capacitor can be electrically coupled to the output 230b or to ground through a corresponding switch 721. In one embodiment, the digital code CODE 725 provided to switches 721 has fewer bits than DIG_CODE provided to MDAC 102. For example, DIG_CODE to MDAC 102 may be 16-bits and CODE 725 to MCDAC 230 may be 4-bits. FIG. 1C illustrates that the frequency problem described therein is much less of a problem at larger code values and, accordingly, MCDAC 230 may provide a benefit with digital codes having fewer bits. In an example, CODE 725 may provide digital code values equal or less than 0x8000 to MCDAC 230. With MCDAC, VOUT can be expressed as:

$$VOUT ( k ) = \frac{C C}{C F B} V R E F + \frac{C [ k ]}{C F B} V REF - \frac{C D A C [ k ]}{C F B} V R E \qquad ( Eq . 4 )$$

where CDAC[k] is the effective capacitance of MCDAC 230 between input 230a and output 230b based on value of CODE 725 (k).

In one embodiment of MCDAC 230, CODE 725 is a fixed digital code CODE_FIXED, e.g., determined by a trimming process and stored in the conversion device 200. In such a trimming process, the output voltage may be measured as a function of frequency at certain low-code values (e.g., 0, 1, 2, 4, 8, 16, etc.). The MCDAC 230 may be enabled to apply the correction and its code swept across various values to determine an appropriate correction. In another embodiment, CODE 725 is based on the fixed digital code CODE_FIXED determined during the trimming process and lower order bits of DIG_CODE (DIG_CODE_LOWER_BITS) input to MDAC 102. For example,

CODE 725=CODE_FIXED+a(DIG_CODE_LOWER_BITS) (EQ. 5)

CODE_FIXED and α may be determined by a trimming process.

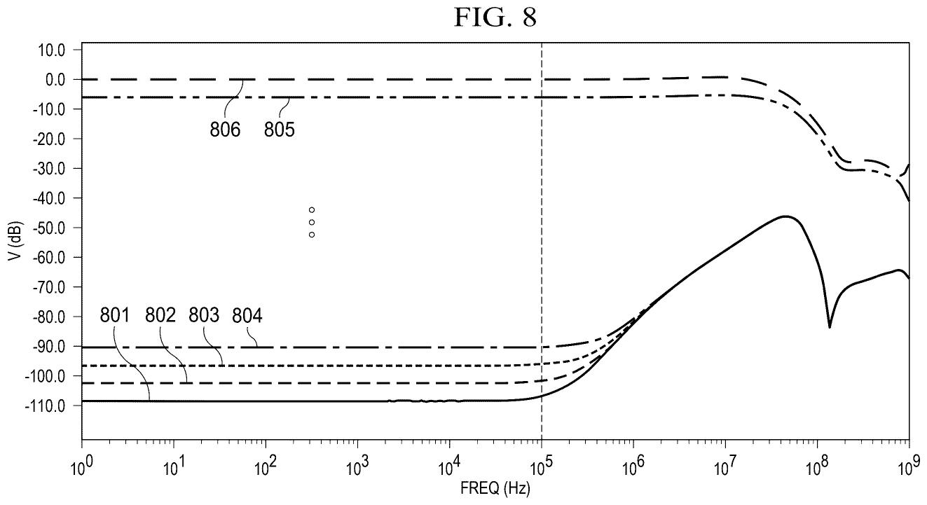

FIG. 8 includes graphs illustrating the frequency performance of the conversion device 1200 with MCDAC and operating with a time-varying reference voltage. Graphs 801-806 correspond to digital codes, DIG_CODE, of 0x0001, 0x0002, 0x0004, 0x0008, 0x8000, and 0xFFFF, respectively. FIG. 8 illustrates that the attenuation corresponding to the code values advantageously is relatively flat from direct current (DC) to approximately 100 KHz.

Example embodiments of the present disclosure are summarized here. Other embodiments can also be understood from the entirety of the specification and the claims filed herein.

Example 1. An apparatus including: a first digital-to-analog converter (DAC) having an input configurable to receive a digital code and having an output; an amplifier having an input coupled to the output of the first DAC; and a second DAC having an input and an output, the input of the second DAC configurable to receive a difference between a first digital code and a second digital code, and the output of the second DAC coupled to the input of the amplifier, the second DAC configurable to provide into the input of the amplifier a current having a magnitude based on the difference between the first and second digital codes.

Example 2. The apparatus of example 1, where the second DAC is configured to provide the current into the input of the amplifier for a fixed duration of time irrespective of the difference between the first and second digital codes.

Example 3. The apparatus of one of examples 1 or 2, where the second DAC is configurable to generate the current in response to the difference between the first and second digital codes being less than a threshold.

Example 4. The apparatus of one of examples 1 to 3, where the magnitude of the current is based on the difference between the first and second digital codes and based on a trim value.

Example 5. The apparatus of one of examples 1 to 4, further including a multiplier having a first input configured to receive the difference between the first and second digital codes and a second input configured to receive the trim value, the multiplier having an output coupled to the input of the second DAC.

Example 6. The apparatus of one of examples 1 to 5, where the second DAC includes a pulse generator having an output, the pulse generator configured to generate a pulse having a width based on a bandwidth of the amplifier.

Example 7. The apparatus of one of examples 1 to 6, where the second DAC includes: resistor segments, each resistor segment having a switch; and switch logic having a first input coupled to the output of the pulse generator and having a second input configured to receive the difference between the first and second digital codes, the switch logic configured to control the switches of the resistor segments based on the pulse from the pulse generator and the difference between the first and second digital codes.

Example 8. The apparatus of one of examples 1 to 7, where: the first DAC includes a first resistor network; and the second DAC includes a second resistor network.

Example 9. The apparatus of one of examples 1 to 8, where the first DAC is configurable to receive a reference voltage having a first polarity, the apparatus further including a third DAC having an input and an output, the input of the third DAC configurable to receive the reference voltage having a second polarity different than the first polarity, and the output of the third DAC coupled to the input of the amplifier.

Example 10. The apparatus of one of examples 1 to 9, where the third DAC is a capacitive DAC.

Example 11. The apparatus of one of examples 1 to 10, further including: a third DAC having an input and an output, the output of the third DAC coupled to the input of the amplifier; and an inverting buffer having an input and an output, the input of the inverting buffer coupled to the third DAC, and the output of the inverting buffer coupled to the first DAC.

Example 12. The apparatus of one of examples 1 to 11, where the current is positive when the difference between the first and second digital codes is positive, and where the current is negative when the difference between the first and second digital codes is negative.

Example 13. The apparatus of one of examples 1 to 12, where the first DAC is configured to receive the second digital code after receiving the first digital code.

Example 14. An apparatus including: a first resistive digital-to-analog converter (DAC) network having an input and terminals; a first switch having control inputs, terminals, and an output, the terminals of the first switch coupled to respective terminals of the first resistive DAC network; a second resistive DAC network having an input and terminals; a second switch having control inputs, terminals, and an output, the terminals of the second switch coupled to respective terminals of the second resistive DAC network, and the output of the second switch coupled to the output of the first switch; and a logic circuit having an input and having outputs, the input configurable to receive a difference between a first digital code and a second digital code, the outputs of the logic circuit coupled to respective control inputs of the first and second switches, the logic circuit including a pulse generator configured to generate a pulse to cause at least one of the first or second resistive DAC networks to generate a current for a time duration based on a width of the pulse, the current having an amplitude based on the difference between the first and second digital codes.

Example 15. The apparatus of example 14, where the amplitude is also based on a trim value.

Example 16. The apparatus of one of examples 14 or 15, where the logic circuit is configured to cause one of the first or second DAC networks to generate the current based on whether the difference between the first and second digital codes is a positive value or a negative value.

Example 17. The apparatus of one of examples 14 to 16, where the logic circuit includes: a first retiming latch having an input and an output, the input of the first retiming latch configurable to receive the difference between the first and second digital codes, and the output of the first retiming latch coupled to the control inputs of the first switch; and a second retiming latch having an input and an output, the input of the second retiming latch configurable to receive the difference between the first and second digital codes, and the output of the second retiming latch coupled to the control inputs of the second switch.

Example 18. An apparatus including: a first digital-to-analog converter (DAC) having an input configurable to receive a reference voltage having a first polarity and having an output; an amplifier having an input coupled to the output of the first DAC; and a second DAC having an input and an output, the input configurable to receive the reference voltage having a second polarity different than the first polarity, and the output of the second DAC coupled to the input of the amplifier.

Example 19. The apparatus of example 18, where the second DAC is a capacitive DAC.

Example 20. The apparatus of one of examples 18 or 19, where the second DAC is a binary-weighted capacitive DAC.

Example 21. The apparatus of one of examples 18 to 20, where the second DAC has a digital input configurable to receive a fixed digital code and the refence voltage is time-varying.

Example 22. The apparatus of one of examples 18 to 21, where the first DAC has a digital input configurable to receive a first range of digital codes, and the second DAC has a digital input configurable to receive a subset of the first range of digital codes.

Example 23. The apparatus of one of examples 18 to 22, where the subset of the first range of digital codes includes digital codes equal to or less than 0x800.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

Circuits described herein may be reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description may include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. An apparatus comprising:
a first digital-to-analog converter (DAC) having an input configurable to receive a digital code and having an output;
an amplifier having an input coupled to the output of the first DAC; and
a second DAC having an input and an output, the input of the second DAC configurable to receive a difference between a first digital code and a second digital code, and the output of the second DAC coupled to the input of the amplifier, the second DAC configurable to provide into the input of the amplifier a current having a magnitude based on the difference between the first and second digital codes.

2. The apparatus of claim 1, wherein the second DAC is configured to provide the current into the input of the amplifier for a fixed duration of time irrespective of the difference between the first and second digital codes.

3. The apparatus of claim 1, wherein the second DAC is configurable to generate the current in response to the difference between the first and second digital codes being less than a threshold.

4. The apparatus of claim 1, wherein the magnitude of the current is based on the difference between the first and second digital codes and based on a trim value.

5. The apparatus of claim 4, further comprising a multiplier having a first input configured to receive the difference between the first and second digital codes and a second input configured to receive the trim value, the multiplier having an output coupled to the input of the second DAC.

6. The apparatus of claim 1, wherein the second DAC includes a pulse generator having an output, the pulse generator configured to generate a pulse having a width based on a bandwidth of the amplifier.

7. The apparatus of claim 6, wherein the second DAC includes:
resistor segments, each resistor segment having a switch; and
switch logic having a first input coupled to the output of the pulse generator and having a second input configured to receive the difference between the first and second digital codes, the switch logic configured to control the switches of the resistor segments based on the pulse from the pulse generator and the difference between the first and second digital codes.

8. The apparatus of claim 1, wherein:
the first DAC includes a first resistor network; and
the second DAC includes a second resistor network.

9. The apparatus of claim 1, wherein the first DAC is configurable to receive a reference voltage having a first polarity, the apparatus further comprising a third DAC having an input and an output, the input of the third DAC configurable to receive the reference voltage having a second polarity different than the first polarity, and the output of the third DAC coupled to the input of the amplifier.

10. The apparatus of claim 9, wherein the third DAC is a capacitive DAC.

11. The apparatus of claim 1, further comprising:
a third DAC having an input and an output, the output of the third DAC coupled to the input of the amplifier; and
an inverting buffer having an input and an output, the input of the inverting buffer coupled to the third DAC, and the output of the inverting buffer coupled to the first DAC.

12. The apparatus of claim 1, wherein the current is positive when the difference between the first and second digital codes is positive, and wherein the current is negative when the difference between the first and second digital codes is negative.

13. The apparatus of claim 1, wherein the first DAC is configured to receive the second digital code after receiving the first digital code.

14. An apparatus comprising:
a first resistive digital-to-analog converter (DAC) network having an input and terminals;
a first switch having control inputs, terminals, and an output, the terminals of the first switch coupled to respective terminals of the first resistive DAC network;
a second resistive DAC network having an input and terminals;
a second switch having control inputs, terminals, and an output, the terminals of the second switch coupled to respective terminals of the second resistive DAC network, and the output of the second switch coupled to the output of the first switch; and
a logic circuit having an input and having outputs, the input configurable to receive a difference between a first digital code and a second digital code, the outputs of the logic circuit coupled to respective control inputs of the first and second switches, the logic circuit including a pulse generator configured to generate a pulse to cause at least one of the first or second resistive DAC networks to generate a current for a time duration based on a width of the pulse, the current having an amplitude based on the difference between the first and second digital codes.

15. The apparatus of claim 14, wherein the amplitude is also based on a trim value.

16. The apparatus of claim 14, wherein the logic circuit is configured to cause one of the first or second DAC networks to generate the current based on whether the difference between the first and second digital codes is a positive value or a negative value.

17. The apparatus of claim 14, wherein the logic circuit includes:
a first retiming latch having an input and an output, the input of the first retiming latch configurable to receive the difference between the first and second digital codes, and the output of the first retiming latch coupled to the control inputs of the first switch; and
a second retiming latch having an input and an output, the input of the second retiming latch configurable to receive the difference between the first and second digital codes, and the output of the second retiming latch coupled to the control inputs of the second switch.

18. An apparatus comprising:
a first digital-to-analog converter (DAC) having an input configurable to receive a reference voltage having a first polarity and having an output;
an amplifier having an input coupled to the output of the first DAC; and
a second DAC having an input and an output, the input configurable to receive the reference voltage having a second polarity different than the first polarity, and the output of the second DAC coupled to the input of the amplifier.

19. The apparatus of claim 18, wherein the second DAC is a capacitive DAC.

20. The apparatus of claim 18, wherein the second DAC is a binary-weighted capacitive DAC.

21. The apparatus of claim 18, wherein the second DAC has a digital input configurable to receive a fixed digital code and the refence voltage is time-varying.

22. The apparatus of claim 18, wherein the first DAC has a digital input configurable to receive a first range of digital codes, and the second DAC has a digital input configurable to receive a subset of the first range of digital codes.

23. The apparatus of claim 22, wherein the subset of the first range of digital codes includes digital codes equal to or less than 0x800.
